(19) United States
(12) Patent Application Publication
(10) Pub. No.: US 2025/0366338 A1
(43) Pub. Date: Nov. 27, 2025

(54) DISPLAY DEVICE, MANUFACTURING METHOD THEREOF, AND ELECTRONIC DEVICE INCLUDING THEREOF

(71) Applicant: Samsung Display Co., LTD., Yongin-si (KR)

(72) Inventors: Seon Uk LEE, Yongin-si (KR); Sun Kyu JOO, Yongin-si (KR); Seok Joon HONG, Yongin-si (KR)

(21) Appl. No.: 18/999,372

(22) Filed: Dec. 23, 2024

(30) Foreign Application Priority Data
May 23, 2024 (KR) 10-2024-0066849

(51) Int. Cl. H10K 59/38; H10K 59/12; H10K 59/122

(52) U.S. Cl. CPC H10K 59/38; H10K 59/1201; H10K 59/122

(57) ABSTRACT

A display device includes a display layer, a light controlling layer on the display layer and including a bank and a color conversion layer, and a color filter layer on the light controlling layer and including a color filter and a light blocking structure, the light controlling layer including: an opening in which the bank is not positioned, and a spacer between the bank and the light blocking structure and partially overlapping the opening.

### CROSS-REFERENCE TO RELATED APPLICATION

The present application claims priority to and the benefit of Korean Patent Application No. 10-2024-0066849, filed on May 23, 2024, in the Korean Intellectual Property Office, the entire disclosure of which is incorporated herein by reference.

### BACKGROUND

### 1. Field

Aspects of the present disclosure relates to a display device, a manufacturing method thereof, and an electronic device including thereof.

### 2. Description of the Related Art

As information technology has developed, importance of a display device, which is a connection medium between a user and information, has been highlighted. Accordingly, the use of display devices such as a liquid crystal display device, an organic light emitting display device, and the like has been increasing.

A display device can be formed by bonding a display panel in which a pixel circuit and a light emitting element are positioned, and an optical panel in which a color filter is disposed. In the process of bonding the display panel and the optical panel, the pixel circuit and/or the light emitting element may be damaged, or the color filter may be damaged. To prevent this, the display panel and/or the optical panel may include a spacer.

The above information disclosed in this Background section is only for enhancement of understanding of the background of the invention and therefore it may contain information that does not form the prior art.

### SUMMARY

Aspects of the present disclosure are directed to a display device, a manufacturing method thereof, and an electronic device including thereof in which damage to layers forming the display device may be prevented or substantially reduced.

According to some embodiments of the present disclosure, there is provides a display device including: a display layer; a light controlling layer on the display layer and including a bank and a color conversion layer; and a color filter layer on the light controlling layer and including a color filter and a light blocking structure, the light controlling layer including: an opening in which the bank is not positioned; and a spacer between the bank and the light blocking structure and partially overlapping the opening.

In some embodiments, a diameter of the spacer is larger than a width of the bank in which the spacer is positioned.

In some embodiments, in a cross-sectional view, a length of an upper surface of the spacer is longer than that of a lower surface of the spacer.

In some embodiments, in a cross-sectional view, the spacer has an inverted trapezoidal shape.

In some embodiments, the upper surface of the spacer is adjacent to the color filter layer, and the lower surface of the spacer is adjacent to the bank.

In some embodiments, in a cross-sectional view, a center of the spacer coincides with a center of the bank in which the spacer is positioned.

In some embodiments, the display device further includes: a sub-pixel area from which light of one color is emitted and a non-sub-pixel area outside the sub-pixel area,
wherein the sub-pixel area includes a first sub-pixel area from which light of a first color is emitted, a second sub-pixel area from which light of a second color is emitted, and a third sub-pixel area from which light of a third color is emitted, and wherein, when viewed in a plan view, the opening has a first opening overlapping the first sub-pixel area, a second opening overlapping the second sub-pixel area, and a third opening overlapping the third sub-pixel area.

In some embodiments, a portion of the first opening, a portion of the second opening, and a portion of the third opening overlap the non-sub-pixel area.

According to some embodiments of the present disclosure, there is provides a display device including: a display layer; a light controlling layer on the display layer and including a bank and a color conversion layer; and a color filter layer on the light controlling layer and including a color filter and a light blocking structure, the light controlling layer including: an opening in which the bank is not positioned; and a spacer between the bank and the light blocking structure, a portion of an upper surface of the spacer overlapping the color filter, and a portion of a lower surface of the spacer overlapping the opening.

In some embodiments, a diameter of the spacer is larger than a width of the bank in which the spacer is positioned.

In some embodiments, in a cross-sectional view, a length of the upper surface of the spacer is longer than that of the lower surface of the spacer.

In some embodiments, the upper surface of the spacer is adjacent to the color filter layer, and the lower surface of the spacer is adjacent to the bank.

In some embodiments, in a cross-sectional view, a center of the spacer coincides with a center of the bank in which the spacer is positioned.

In some embodiments, the display layer includes a light emitting element that provides light to a light emitting area, the light emitting area overlaps the color filter and the color conversion layer when viewed in a plan view, and a portion of the spacer overlaps the light emitting area.

In some embodiments, a filling layer is between the light controlling layer and the color filter layer, and the filling layer and the spacer have the same refractive index.

According to some embodiments of the present disclosure, there is provides a manufacturing method of a display device, including: manufacturing a first panel; manufacturing a second panel; and interposing a filling layer between the first panel and the second panel and bonding the first panel and the second panel, wherein the manufacturing of the first panel includes: forming a color filter layer including a color filter and a light blocking portion on a first base layer; and forming a spacer on the light blocking portion.

In some embodiments, the manufacturing of the second panel includes: positioning a light emitting element layer including a light emitting element on a second base layer; and positioning a color conversion layer including a bank protruding in a thickness direction of the second base layer and a color conversion unit within an area surrounded by the bank and including quantum dots.

In some embodiments, the bonding of the first panel and the second panel includes: bonding the first panel and the second panel so that a center of the bank coincides with that of the spacer in a cross-sectional view.

In some embodiments, a diameter of the spacer is larger than a width of the bank in which the spacer is positioned.

In some embodiments, an upper surface of the spacer is adjacent to the first panel and a lower surface of the spacer is adjacent to the second panel, and in a cross-sectional view, a length of the upper surface of the spacer is longer than that of the lower surface of the spacer.

According to some embodiments of the present disclosure, there is provides an electronic device. The electronic device includes a processor to provide image data signals; and a display device to display an image based on the image data signals. The display device including: a display layer; a light controlling layer on the display layer and including a bank and a color conversion layer; and a color filter layer on the light controlling layer and including a color filter and a light blocking structure, the light controlling layer including: an opening in which the bank is not positioned; and a spacer between the bank and the light blocking structure and partially overlapping the opening.

In some embodiments, a diameter of the spacer is larger than a width of the bank in which the spacer is positioned.

In some embodiments, in a cross-sectional view, a length of an upper surface of the spacer is longer than that of a lower surface of the spacer.

In some embodiments, in a cross-sectional view, the spacer has an inverted trapezoidal shape.

According to some embodiments of the present disclosure, it is possible to provide a display device and a manufacturing method thereof in which damage to layers forming the display device may be prevented or substantially reduced.

According to some embodiments of the present disclosure, a display device with improved process convenience may be provided.

According to some embodiments of the present disclosure, a display device with high resolution and improved display quality and a manufacturing method thereof may be provided.

### BRIEF DESCRIPTION OF THE DRAWINGS

FIG. 1 illustrates a schematic top plan view of a display device according to some embodiments of the present disclosure.

FIG. 2 illustrates a schematic cross-sectional view of a display device according to some embodiments of the present disclosure.

FIG. 3 illustrates a schematic view of a display layer according to some embodiments of the present disclosure.

FIG. 4 to FIG. 6 illustrate schematic top plan views of a display device according to some embodiments of the present disclosure.

FIG. 7 illustrates a schematic cross-sectional view taken along the line A-A′ of FIG. 4 to FIG. 6, according to some embodiments of the present disclosure.

FIG. 8 to FIG. 10 illustrate schematic top plan views of a display device according to some other embodiments of the present disclosure.

FIG. 11 illustrates a schematic cross-sectional view taken along the line B-B′ of FIG. 8 to FIG. 10, according to some embodiments of the present disclosure.

FIG. 12 illustrates a flowchart of a manufacturing method of a display device according to some embodiments of the present disclosure.

FIG. 13 illustrates a flowchart of the process of manufacturing a first panel of FIG. 12, according to some embodiments of the present disclosure.

FIG. 14 and FIG. 15 illustrate schematic views of the process of a manufacturing method of a display device of FIG. 13, according to some embodiments of the present disclosure.

FIG. 16 illustrates a flowchart of the process of manufacturing a second panel of FIG. 12, according to some embodiments of the present disclosure.

FIG. 17 and FIG. 18 illustrate schematic views of the process of a manufacturing method of a display device of FIG. 16, according to some embodiments of the present disclosure.

FIG. 19 illustrates a schematic view of the process of bonding the first panel and the second panel of FIG. 12, according to some embodiments of the present disclosure.

FIG. 20 illustrates a block diagram of a display device according to an embodiment.

FIG. 21 is a block diagram of an electronic device according to an embodiment.

FIG. 22 shows schematic views of various embodiments of an electronic device.

### DETAILED DESCRIPTION

Because the present disclosure may be variously modified and have various forms, embodiments will be illustrated and described in detail in the following. This, however, by no means restricts the invention to the specific embodiments, and it is to be understood as embracing all included in the spirit and scope of the present disclosure changes, equivalents, and substitutes.

It will be understood that, although the terms “first”, “second”, “third”, etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section discussed below could be termed a second element, component, region, layer or section, without departing from the spirit and scope of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. In addition, it will also be understood that when a layer is referred to as being “between” two layers, it can be the only layer between the two layers, or one or more intervening layers may also be present.

The terminology used herein is for the purpose of describing particular embodiments and is not intended to be limiting of the inventive concept. As used herein, the singular forms “a” and “an” are intended to include the plural forms as well, unless the context clearly indicates otherwise. It will be further understood that the terms “include,” “including,” “comprises,” “comprising,” “has,” “have,” and “having,” when used in this specification, specify the presence of stated features, integers, steps, operations, elements, and/or components, but do not preclude the presence or addition of one or more other features, integers, steps, operations, elements, components, and/or groups thereof.

As used herein, the term “and/or” includes any and all combinations of one or more of the associated listed items. For example, the expression “A and/or B” denotes A, B, or A and B. Expressions such as “one or more of” and “at least one of,” when preceding a list of elements, modify the entire list of elements and do not modify the individual elements of the list. For example, the expression “one or more of A, B, and C,” “at least one of A, B, or C,” “at least one of A, B, and C,” and “at least one selected from the group consisting of A, B, and C” indicates only A, only B, only C, both A and B, both A and C, both B and C, or all of A, B, and C.

Further, the use of “may” when describing embodiments of the inventive concept refers to “one or more embodiments of the inventive concept.” Also, the term “exemplary” is intended to refer to an example or illustration.

It will be understood that when an element or layer is referred to as being “on”, “connected to”, “coupled to”, or “adjacent” another element or layer, it can be directly on, connected to, coupled to, or adjacent the other element or layer, or one or more intervening elements or layers may be present. When an element or layer is referred to as being “directly on,” “directly connected to”, “directly coupled to”, “in contact with”, “in direct contact with”, or “immediately adjacent” another element or layer, there are no intervening elements or layers present.

As used herein, the term “substantially,” “about,” and similar terms are used as terms of approximation and not as terms of degree, and are intended to account for the inherent variations in measured or calculated values that would be recognized by those of ordinary skill in the art. Further, if the term “substantially” is used in combination with a feature that could be expressed using a numeric value, the term “substantially” denotes a range of +/−5% of the value centered on the value. Furthermore, a specific quantity or range recited in this written description or the claims may also encompass the inherent variations in measured or calculated values that would be recognized by those of ordinary skill in the art.

As used herein, the terms “use,” “using,” and “used” may be considered synonymous with the terms “utilize,” “utilizing,” and “utilized,” respectively.

When one or more embodiments may be implemented differently, a specific process order may be performed differently from the described order. For example, (i) the disclosed operations of a process are merely examples, and may involve various additional operations not explicitly covered, and (ii) the temporal order of the operations may be varied.

Unless otherwise defined, all terms (including technical and scientific terms) used herein have the same meaning as commonly understood by one of ordinary skill in the art to which the present inventive concept belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Aspects of embodiments of the present disclosure are directed to a display device and a manufacturing method thereof. Hereinafter, a display device and a manufacturing method thereof according to some embodiments will be described with reference to the accompanying drawings.

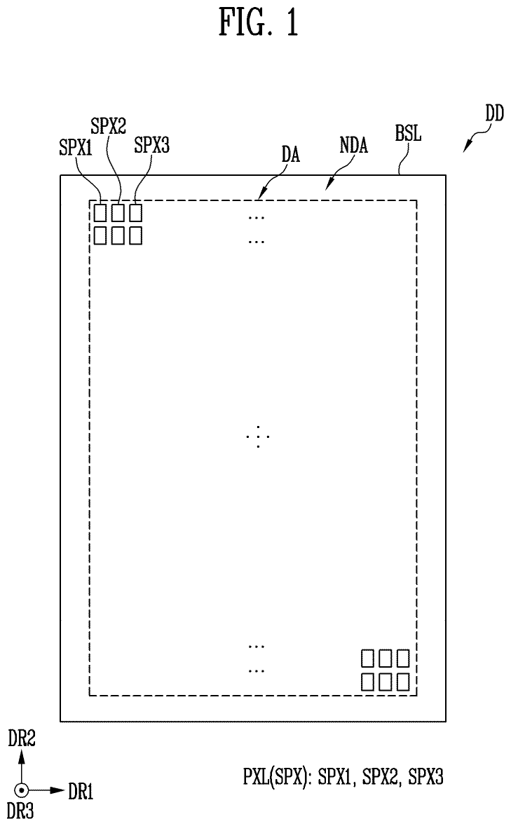

FIG. 1 illustrates a schematic top plan view of a display device according to some embodiments of the present disclosure.

Referring to FIG. 1, a display device DD may include a base layer BSL, and a pixel PXL disposed on the base layer BSL. The display device DD may further include a driving circuit portion (e.g., a scan driver and a data driver) for driving the pixel PXL, wires, and pads.

The display device DD (or the base layer BSL) may include a display area DA and a non-display area NDA. The non-display area NDA may refer to an area other than the display area DA. The non-display area NDA may surround at least a portion of the display area DA.

The base layer BSL may form a base surface of the display device DD. In some embodiments, the base layer BSL may be a lower substrate for disposing layers forming the display device DD. The base layer BSL may be a rigid or flexible substrate or film. For example, the base layer BSL may include a glass material. In some examples, the base layer BSL may include a silicon material. In other examples, the base layer BSL may include polyimide. However, the present disclosure is not limited thereto.

The display area DA may refer to an area in which the pixels PXL are disposed. The non-display area NDA may refer to an area in which the pixel PXL is not disposed. In the non-display area NDA, a driving circuit portion, wires, and pads connected to the pixel PXL of the display area DA may be disposed.

According to some embodiments, the pixel PXL (or sub-pixel SPX) may be arranged according to a stripe or pentile (PENTILE™) arrangement structure, but the present disclosure is not limited thereto, and various examples may be applied to the present disclosure.

According to some embodiments, the pixel PXL (or the sub-pixels SPX) may include the first sub-pixel SPX1, the second sub-pixel SPX2, and the third sub-pixel SPX3. Each of the first sub-pixel SPX1, the second sub-pixel SPX2, and the third sub-pixel SPX3 may be a sub-pixel. At least one of the first sub-pixel SPX1, the second sub-pixel SPX2, and the third sub-pixel SPX3 may form one pixel unit capable of emitting light of various suitable colors.

Each of the first sub-pixel SPX1, the second sub-pixel SPX2, and the third sub-pixel SPX3 may emit light of one color.

For example, the first sub-pixel SPX1 may be a red pixel emitting red (e.g., first color) light, the second sub-pixel SPX2 may be a green pixel emitting green (e.g., second color) light, and the third sub-pixel SPX3 may be a blue pixel emitting blue (e.g., third color) light. The red pixel may provide light in a wavelength band of about 600 nm to about 750 nm. The green pixel may provide light in a wavelength band of about 480 nm to about 560 nm. The blue pixel may provide light in a wavelength band of about 370 nm to about 460 nm.

According to some embodiments, the number of the second sub-pixels SPX2 may be greater than the number of the first sub-pixels SPX1 and the number of the third sub-pixels SPX3. However, the color, type, and/or number of the first sub-pixel SPX1, the second sub-pixel SPX2, and the third sub-pixel SPX3 forming each pixel unit described above are not limited to a specific example.

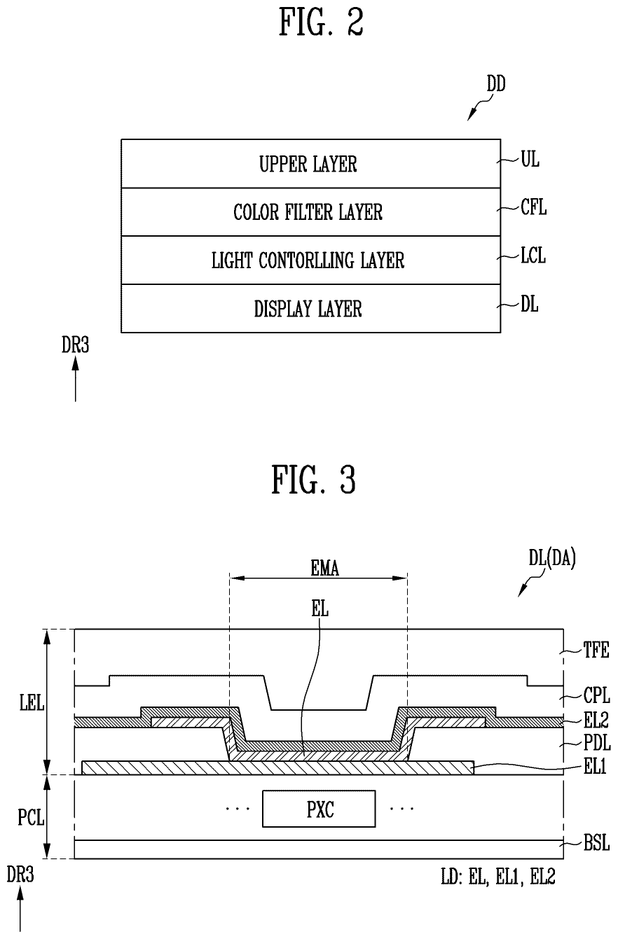

A general structure including a cross-sectional structure of the display device DD according to some embodiments will be described with reference to FIG. 2 and FIG. 3.

FIG. 2 illustrates a schematic cross-sectional view of a display device according to some embodiments of the present disclosure. FIG. 3 illustrates a schematic view of a display layer according to some embodiments of the present disclosure.

Referring to FIG. 2 and FIG. 3, the display device DD may include a display layer DL, a light controlling layer LCL, a color filter layer CFL, and an upper layer UL.

The display layer DL may be configured to emit light. The display layer DL may form a base on which the light controlling layer LCL is disposed.

The display layer DL may include a pixel circuit layer PCL including the base layer BSL, and a light emitting element layer LEL including a light emitting element LD to be able to form the pixel PXL.

The base layer BSL may form a base on which a pixel circuit PXC is disposed. The pixel circuit PXC may be disposed on the base layer BSL and may be configured to drive the light emitting element LD. The pixel circuit layer PCL may include conductive layers and insulating layers, and the conductive layers may form the pixel circuit PXC. The pixel circuit PXC may include circuit elements capable of driving the sub-pixel SPX (or the light emitting element LD). The circuit elements may include a driving transistor, and may also include additional transistors and capacitors.

The light emitting element layer LEL may be disposed on the pixel circuit layer PCL. In some embodiments, the light emitting element layer LEL may include the light emitting element LD.

For example, the light emitting element LD may include an organic light emitting diode (OLED) containing an organic material. FIG. 3 schematically illustrates some embodiments in which the light emitting element LD is an organic light emitting diode, and a cross-sectional structure of the display device DD in the display area DA, which schematically shows a cross-sectional structure of the display layer DL including the pixel circuit layer PCL and the light emitting element layer LEL.

In some embodiments, the light emitting element layer LEL may further include a pixel defining film PDL, a capping layer CPL, and an encapsulation film TFE.

In some embodiments, the light emitting element LD may be disposed on the pixel circuit layer PCL. The light emitting element LD may include a first light emitting element included in the first sub-pixel SPX1, a second light emitting element included in the second sub-pixel SPX2, and a third light emitting element included in the third sub-pixel SPX3.

In some embodiments, the light emitting element LD may include a first electrode EL1, a light emitting portion EL, and a second electrode EL2. In some embodiments, the light emitting portion EL may be disposed in an area defined by the pixel defining film PDL. One surface of the light emitting portion EL may be electrically connected to the first electrode EL1, and the other surface of the light emitting portion EL may be electrically connected to the second electrode EL2.

In some embodiments, the light emitting element LD may form a light emitting area EMA. The light emitting area EMA may be an area in which light emitted by the light emitting element LD is provided. In some embodiments, the light emitting area EMA may correspond to an area in which the first electrode EL1 is exposed by the pixel defining film PDL. However, the present disclosure is not limited thereto.

The first electrode EL1 may be an anode electrode for the light emitting portion EL, and the second electrode EL2 may be a cathode electrode for the light emitting portion EL. In some embodiments, the first electrode EL1 and the second electrode EL2 may include a conductive material. For example, the conductive material may include gold (Au), silver (Ag), aluminum (AI), molybdenum (Mo), chromium (Cr), titanium (Ti), nickel (Ni), neodymium (Nd), copper (Cu), platinum (Pt), and/or the like. In some examples, the conductive material may include a silver nanowire (AgNW), an indium tin oxide (ITO), an indium zinc oxide (IZO), an indium gallium zinc oxide (IGZO), an antimony zinc oxide (AZO), a zinc oxide (ZnO), a tin oxide (SnO2), a carbon nano tube, graphene, and/or the like. However, the present disclosure is not necessarily limited thereto.

The light emitting portion EL may emit light based on an electrical signal provided from the anode electrode (e.g., the first electrode EL1) and the cathode electrode (e.g., the second electrode EL2).

The light emitting portion EL may include a multi-layered structure. For example, each light emitting portion EL may include a plurality of light emitting structures including a hole transport portion, a light emitting layer (or a light generation layer), and an electron transport portion. Respective layers forming the light emitting structure may include an organic material, and in some embodiments, they may further include an inorganic material such as a metal-containing compound or quantum dot.

In some embodiments, the light emitting portion EL may not include a light component of the second color and may emit light of a third color including a light component of the third color. For example, the plurality of light emitting structures may include a multilayer structure emitting light of the third color. Accordingly, the light emitted by the light emitting portion EL may be light of the third color.

In some examples, the light emitting portion EL may include a tandem structure. For example, the light emitting portion EL may emit light of one color including the light component of the second color and the light component of the third color. For example, the plurality of light emitting structures may include a first light emitting structure and a second light emitting structure. The first light emitting structure may include a multilayer structure that emits light of the second color. The second light emitting structure may include a multilayer structure that emits light of the third color. Accordingly, the light emitted by the light emitting portion EL may be a mixture of the second color and the third color.

The hole transport portion may include a multi-layered structure having a plurality of layers each containing different materials. For example, the hole transport portion may include at least one of a hole injection layer and a hole transport layer, and in some embodiments, it may further include a light emitting auxiliary layer and an electron blocking layer. For example, the hole transport portion may have a multi-layered structure such as a hole injection layer/hole transport layer, a hole injection layer/hole transport layer/light emitting auxiliary layer, a hole transport layer/light emitting auxiliary layer, an electron blocking layer/hole injection layer/hole transport layer, hole transport layers that are sequentially disposed and include different materials, or a hole injection layer/hole transport layer/electron blocking layer. However, the present disclosure is not limited to specific examples.

The light emitting layer may include a material that may emit light of one color. The light emitting layer may include a host and a dopant. The host of the light emitting layer is a light emitting material that may capture carriers (e.g., electrons and holes) for light generation, and may induce excitons to be efficiently generated. The dopant may include a phosphorescent dopant or a fluorescent dopant. In some embodiments, examples of the dopant are not particularly limited. In some embodiments, the dopant may include an organic material or a metal complex.

The electron transport portion may include a multi-layered structure having a plurality of layers each containing different materials. The electron transport portion may include at least one of an electron injection layer and an electron transport layer, and in some embodiment, it may further include an electron buffer layer and a hole blocking layer. For example, the electron transport portion may have a multi-layered structure such as an electron transport layer/electron injection layer, a hole blocking layer/electron transport layer/electron injection layer, an electron control layer/electron transport layer/electron injection layer, or a buffer layer/electron transport layer/electron injection layer. However, the present disclosure is not limited to specific examples.

The pixel defining film PDL may be disposed on the pixel circuit layer PCL to define a position at which the light emitting portion EL is disposed. The pixel defining film PDL may include an organic material. For example, the pixel defining film PDL may include an acrylic resin, an epoxy resin, a phenol resin, a polyamide resin, a polyimide resin, and/or the like. However, the present disclosure is not limited thereto. In some other embodiments, the pixel defining film PDL may include an inorganic material. For example, the pixel defining film PDL may include a silicon oxide (SiOx), a silicon nitride (SiNx), and/or the like. In some embodiments, the pixel defining film PDL may have a multi-layered structure in which a layer containing a silicon oxide (SiOx) and a layer containing a silicon nitride (SiNx) are stacked.

The capping layer CPL may be disposed on the second electrode EL2. The capping layer CPL may cap the second electrode EL2. The capping layer CPL may include an inorganic material.

The encapsulation film TFE may be disposed on the light emitting element LD (e.g., the second electrode EL2). The encapsulation film TFE may offset a level difference generated by the light emitting element LD and the pixel defining film PDL. The encapsulation film TFE may include a plurality of insulating films covering the light emitting element LD. In some embodiments, the encapsulation film TFE may have a structure in which an inorganic film and an organic film are alternately stacked. In some embodiments, the encapsulation film TFE may be a thin encapsulation film.

In some embodiments, the light emitting element LD may be an inorganic light emitting diode containing an inorganic material. In some examples, as described above, the light emitting element LD may emit light of the third color. In other examples, the light emitting element LD may emit light including a light component of the second color and a light component of the third color.

The light controlling layer LCL may be disposed on the display layer DL (e.g., light emitting element layer LEL). For example, the light controlling layer LCL may be disposed on an upper side of the display layer DL based on a display direction (e.g., third direction DR3).

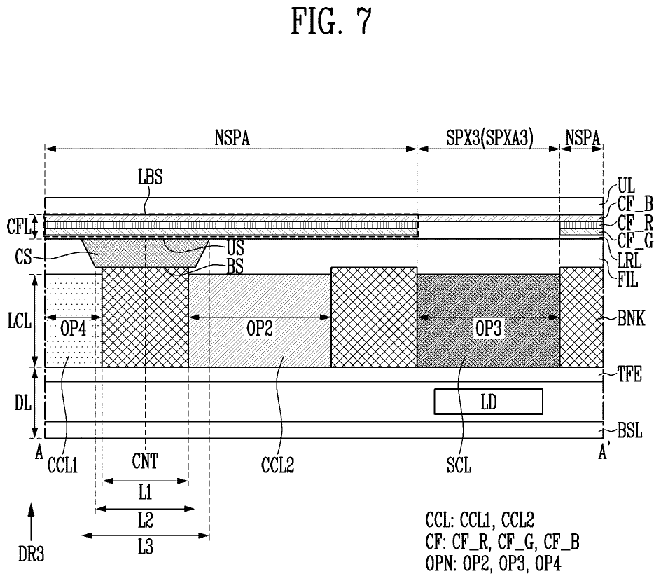

In some embodiments, the light controlling layer LCL may change the color of the applied light and may be a layer that scatters the applied light. For example, the light controlling layer LCL may include a color conversion layer CCL (see, e.g., FIG. 7) and a scattering layer SCL (see, e.g., FIG. 7).

The color filter layer CFL may be disposed on the light controlling layer LCL. For example, the color filter layer CFL may be disposed on the upper side of the light controlling layer LCL based on the display direction (e.g., third direction DR3).

In some embodiments, the color filter layer CFL may include color filters CF_R, CF_G, and CF_B (see, e.g., FIG. 7) that selectively transmit light of one color.

The upper layer UL may be disposed on the color filter layer CFL. For example, the upper layer UL may be disposed on an upper side of the color filter layer CFL based on the display direction (e.g., third direction DR3).

In some embodiments, the upper layer UL may include an upper substrate (e.g., glass substrate). In some examples, the upper layer UL may include an upper film layer. However, the present disclosure is not limited to a specific example.

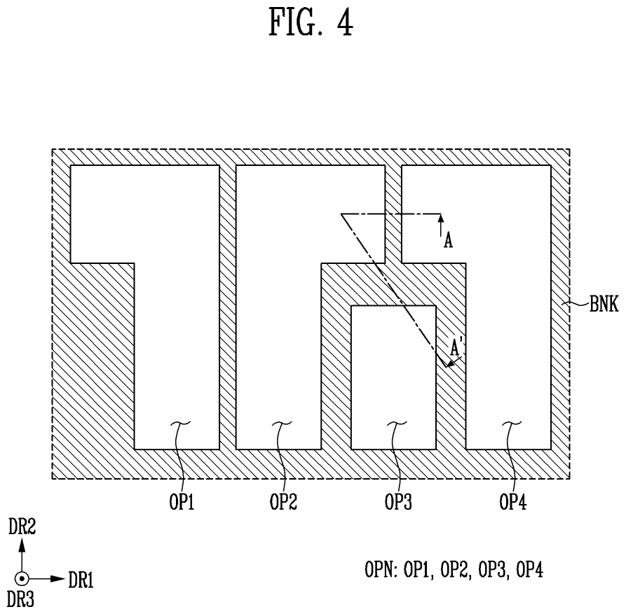

The display device DD according to some embodiments will be described with reference to FIG. 4 to FIG. 7. Descriptions that may be redundant to those provided above are either simplified or are not repeated.

FIG. 4 to FIG. 6 illustrate schematic top plan views of a display device according to some embodiments of the present disclosure. FIG. 7 illustrates a schematic cross-sectional view taken along the line A-A′ of FIG. 4 to FIG, according to some embodiments of the present disclosure. 6. FIG. 4 to FIG. 6 illustrate the first to third sub-pixels SPX1, SPX2, and SPX3 (see, e.g., FIG. 1) of the first pixel and the fourth sub-pixel SPX4 of the second pixel adjacent to the first pixel, and illustrate the same area.

For example, the first sub-pixel SPX1 and the fourth sub-pixel SPX4 may be a red pixel emitting red (e.g., first color) light, and the second sub-pixel SPX2 may be a green pixel emitting green (e.g., second color) light, and the third sub-pixel SPX3 may be a blue pixel emitting blue (e.g., third color) light.

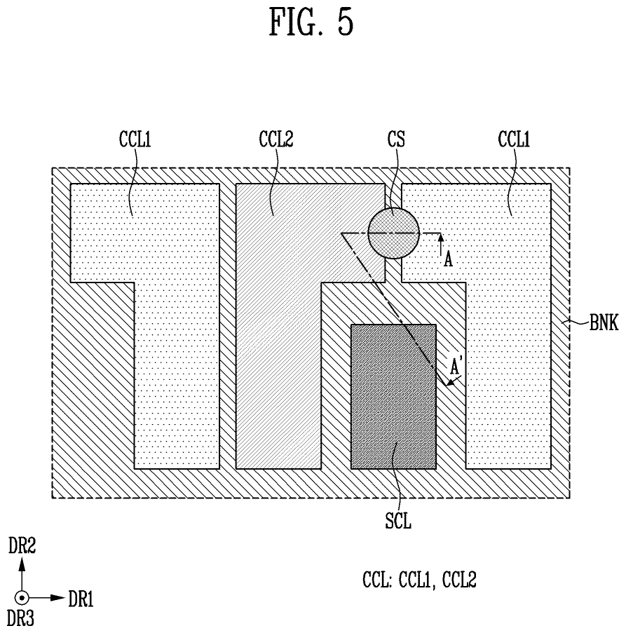

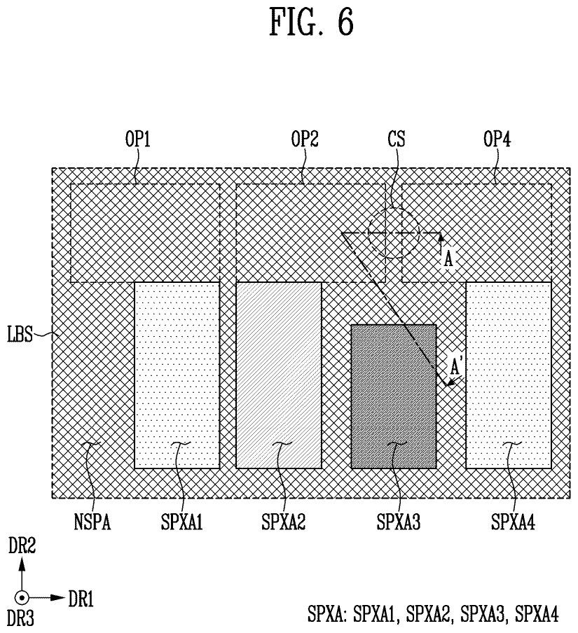

FIG. 4 schematically illustrates a bank BNK. FIG. 5 schematically illustrates a bank BNK, a color conversion layer CCL, and a scattering layer SCL. FIG. 6 schematically illustrates a light blocking structure LBS. Based on FIG. 4 to FIG. 7, a disposition relationship of the components will be more clearly understood.

Referring to FIG. 4 to FIG. 7, the display device DD (e.g., the pixel PXL) may include the bank BNK.

The bank BNK may be patterned within the display area DA. The bank BNK may not be disposed within a partial area in the display area DA. For example, the bank BNK may form an opening OPN. The bank BNK may protrude in the thickness direction (e.g., third direction DR3) of the base layer BSL and may surround the opening OPN. The bank BNK may expose the display layer DL (e.g., the encapsulation layer TFE) in the opening OPN. The bank BNK may not be disposed in the opening OPN.

In some embodiments, the bank BNK may include an acrylic resin, an epoxy resin, a phenol resin, a polyamide resin, a polyimide resin, and/or the like. In some embodiments, the bank BNK may include a light blocking material (e.g., black matrix). However, the present disclosure is not limited thereto.

In some embodiments, the opening OPN may be an area in which ink is supplied in an inkjet process for forming the color conversion layer CCL.

In some embodiments, the first to fourth openings OP1 to OP4 may be disposed along the first direction DR1. In addition, the sizes of the first to fourth openings OP1 to OP4 may be different. For example, the third opening OP3 may be formed to be smaller than the first opening OP1. In some embodiments, the first to fourth openings OP1 to OP4 may be spaced apart from each other based on the first direction DR1 when viewed in a plan view.

The plane defined in the present specification is a direction extending in the first direction DR1 and the second direction DR2, and may be defined based on a plane on which the base layer BSL is disposed. In some embodiments, the third direction DR3 may be a thickness direction of the base layer BSL, and the third direction DR3 may be a light emitting direction of the display device DD.

The display device DD (e.g., the pixel PXL) may include the color conversion layer CCL and the scattering layer SCL disposed within the display area DA.

The color conversion layer CCL may be patterned within the display area DA. The color conversion layer CCL may be disposed within an area surrounded by the bank BNK. When viewed in a plan view, the color conversion layer CCL may not overlap the bank BNK.

The color conversion layer CCL may be configured to change the color of one color of light. For example, the color conversion layer CCL may include a first color conversion layer CCL1 and a second color conversion layer CCL2. In some embodiments, the color conversion layer CCL may be formed based on an inkjet process.

The first color conversion layer CCL1 may be a layer for forming the first sub-pixel SPX1. The first color conversion layer CCL1 may include first color conversion particles that convert light (e.g., light including a light component of the third color) provided by the light emitting element LD into light of the first color. For example, the first color conversion layer CCL1 may include a first quantum-dot that converts light of the third color into light of the first color. The first quantum-dot may absorb light of the third color and shift the wavelength according to energy transition to emit light of the first color. The first quantum-dot may be dispersed and provided in a matrix layer such as an organic material included within the first color conversion layer CCL1.

Referring to FIG. 5, the first color conversion layer CCL1 may be disposed within the first opening OP1 and the fourth opening OP4.

The second color conversion layer CCL2 may be a layer for forming the second sub-pixel SPX2. The second color conversion layer CCL2 may include second color conversion particles that convert light (e.g., light including a light component of the third color) provided by the light emitting element LD into light of the second color. For example, the second color conversion layer CCL2 may include a second quantum-dot that converts light of the third color into light of the second color. The second quantum-dot may absorb light of the third color and shift the wavelength according to energy transition to emit light of the second color. The second quantum-dot may be dispersed and provided in a matrix layer such as an organic material included in the second color conversion layer CCL2.

Referring to FIG. 4 and FIG. 5, the second color conversion layer CCL2 may be disposed within the second opening OP2.

The scattering layer SCL may be patterned within the display area DA. The scattering layer SCL may be disposed within an area surrounded by the bank BNK. When viewed in a plan view, the scattering layer SCL may not overlap the bank BNK.

The scattering layer SCL may be a layer for improving light emission efficiency of the display device DD and improving viewing angle characteristics. The scattering layer SCL may include scatterers. The scatterers may be dispersed and provided in a matrix layer such as an organic material (e.g., a transparent organic material) included in the scattering layer SCL. In some embodiments, the scatterers may include various suitable light scattering particles. For example, the scatterer may include a titanium oxide (TiOx), a silica (SiOx) (e.g., a silica bead, a hollow silica, or the like), a zirconium oxide (ZrOx), an aluminum oxide (AlxOy), an indium oxide (InxOy), a zinc oxide (ZnOx), a tin oxide (SnOx), an antimony oxide (SbxOy), and/or the like. However, the present disclosure is not limited thereto.

Referring to FIG. 4 and FIG. 5, the scattering layer SCL may be disposed within the third opening OP3.

In some embodiments, the display device DD may further include a spacer CS. When viewed in a plan view, the spacer CS may overlap the second opening OP2, the fourth opening OP4, and the bank BNK.

The spacer CS may form a separation distance between other components of the light controlling layer LCL and the color filter layer CFL. In this case, when the display device DD is manufactured with a filling layer FIL interposed between the color filter layer CFL and the light controlling layer LCL, damage to each layer of the display device DD may be prevented or substantially reduced.

In some embodiments, the display device DD may include a sub-pixel area SPXA in which one color of light is provided and a non-sub-pixel area NSPA in which one color of light is not provided. The display device DD may include a light blocking structure LBS.

In some embodiments, the sub-pixel area SPXA may include first to fourth sub-pixel areas SPXA1 to SPXA4. The first sub-pixel area SPXA1 and the fourth sub-pixel area SPXA4 may be areas in which light of the first color is provided, and may be areas in which the first color conversion layer CCL1 is disposed. The second sub-pixel area SPXA2 may be an area in which light of the second color is provided, and may be an area in which the second color conversion layer CCL2 is disposed. The third sub-pixel area SPXA3 may be an area in which light of the third color is provided, and may be an area in which the scattering layer SCL is disposed.

When viewed in a plan view, the light blocking structure LBS may not overlap the sub-pixel area SPXA and may be disposed within the non-sub-pixel area NSPA. Because the light blocking structure LBS is formed, the risk of color mixing between the sub-pixels SPX may be reduced.

In some embodiments, when viewed in a plan view, the area of the opening OPN that does not overlap the light blocking structure LBS may be the sub-pixel area SPXA, and the area of the opening OPN that overlaps the light blocking structure LBS may be the non-sub-pixel area NSPA.

For example, when viewed in a plan view, the area of the first opening OP1 that does not overlap the light blocking structure LBS may be the first sub-pixel area SPXA1, and the area of the first opening OP1 that overlaps the light blocking structure LBS may be the non-sub-pixel area NSPA.

When viewed in a plan view, the area of the second opening OPN2 that does not overlap the light blocking structure LBS may be the second sub-pixel area SPXA2, and the area of the second opening OPN2 that overlaps the light blocking structure LBS may be the non-sub-pixel area NSPA.

When viewed in a plan view, the area of the third opening OPN3 that does not overlap the light blocking structure LBS may be the third sub-pixel area SPXA3, and the area of the third opening OPN3 that overlaps the light blocking structure LBS may be the non-sub-pixel area NSPA. Although FIG. 6 illustrates that the third opening OP3 and the third sub-pixel area SPXA3 are the same, the present disclosure is not limited thereto.

When viewed in a plan view, the area of the fourth opening OPN4 that does not overlap the light blocking structure LBS may be the fourth sub-pixel area SPXA4, and the area of the fourth opening OPN4 that overlaps the light blocking structure LBS may be the non-sub-pixel area NSPA.

In some embodiments, the spacer CS may be disposed between the bank BNK and the color filter layer CFL. The upper surface US of the spacer CS may overlap the light blocking structure LBS. A portion of the lower surface BS of the spacer CS may overlap the bank BNK, and the remaining portion thereof may overlap the opening OPN.

As the area of the opening OPN is enlarged to maximize the aperture ratio of the opening OPN, a spacer CS overlapping a portion of the opening OPN may be provided. Accordingly, the spacer CS may be provided while securing the maximum aperture ratio, thereby increasing the efficiency and lifespan of the display device DD.

Referring to FIG. 7, in a cross-sectional view, the length L1 of the bank BNK overlapping the spacer CS may be shorter than the length L2 of the lower surface BS of the spacer CS. In addition, in a cross-sectional view, the length L1 of the bank BNK may be shorter than the length L3 of the upper surface US of the spacer CS.

That is, the diameter of the spacer CS may be greater than the width of the bank BNK overlapping the spacer CS. Accordingly, when the spacer CS is disposed on the bank BNK, an alignment margin may be secured.

In some embodiments, the length L3 of the upper surface US of the spacer CS may be longer than the length L2 of the lower surface BS of the spacer CS. Accordingly, the spacer CS may have a cross-section of an inverted trapezoidal shape.

In addition, in a cross-sectional view, the center of the spacer CS and the center of the bank BNK may coincide (e.g., align). For example, the center of the spacer CS and the center of the bank BNK may coincide (e.g., align) at the center point CNT.

In some embodiments, the light controlling layer LCL, the color filter layer CFL, and the upper layer UL may be disposed on the display layer DL.

The light emitting element LD formed in the display layer DL may be disposed in each of the sub-pixel areas SPXA. For example, the light emitting element LD may include a first light emitting element included in the first sub-pixel SPX1 and disposed within the first sub-pixel area SPXA1, a second light emitting element included in the second sub-pixel SPX2 and disposed within the second sub-pixel area SPXA2, a third light emitting element included in the third sub-pixel SPX3 and disposed within the third sub-pixel area SPXA3, and a fourth light-emitting element included in the fourth sub-pixel and disposed within the fourth sub-pixel area SPXA4.

In some embodiments, the light emitting area EMA formed by the light emitting element LD may overlap the sub-pixel area SPXA when viewed in a plan view.

The light emitting area EMA (or the light emitting element LD) may overlap the color conversion layer CCL and the color filter CF when viewed in a plan view. The light emitting area EMA (or the light emitting element LD) may overlap the scattering layer SCL and the color filter CF when viewed in a plan view.

The light controlling layer LCL may be disposed on the display layer DL (e.g., the encapsulation layer TFE). As described above, the light controlling layer LCL may include the color conversion layer CCL, the scattering layer SCL, and the bank BNK.

The bank BNK may expose an upper surface of the display layer DL (e.g., an upper surface of the encapsulation layer TFE).

In some embodiments, the display device DD may further include a filling layer FIL interposed between the light controlling layer LCL and the color filter layer CFL. The filling layer FIL may include various suitable transparent organic materials, examples of which are not particularly limited. In some embodiments, a first panel in which the light controlling layer LCL is disposed on the display layer DL including the base layer BSL is manufactured, a second panel in which the color filter layer CFL is disposed on the upper layer UL is manufactured, and the filling layer FIL is interposed between the first panel and the second panel so that the first panel and the second panel are coupled to manufacture the display device DD. However, the present disclosure is not necessarily limited thereto.

The color filter layer CFL may be disposed on the light controlling layer LCL (e.g., on the filling layer FIL). The color filter layer CFL may be formed under the upper layer UL. The color filter layer CFL may include color filters CF, an optical layer LRL, and an upper capping layer CPL_U.

In some embodiments, the color filters CF may include a first color filter CF_R for forming the first sub-pixel SPX1, a second color filter CF_G for forming the second sub-pixel SPX2, and a third color filter CF_B for forming the third sub-pixel SPX3.

The first color filter CF_R may be disposed within the first sub-pixel area SPXA1. The first color filter CF_R may include a color filter material (e.g., a dye or pigment) that selectively transmits light of the first color (e.g., red).

The second color filter CF_G may be disposed within the second sub-pixel area SPXA2. The second color filter CF_G may include a color filter material (e.g., a dye or pigment) that selectively transmits light of the second color (e.g., green).

The third color filter CF_B may be disposed within the third sub-pixel area SPXA3. The third color filter CF_B may include a color filter material (e.g., a dye or pigment) that selectively transmits light of the third color (e.g., blue).

In some embodiments, the non-sub-pixel area NSPA in which light of one color may not be visually recognized may be formed between the sub-pixel areas SPXA. For example, when viewed in a plan view, in the non-sub-pixel area NSPA, the light blocking structure LBS in which the first color filter CF_R, the second color filter CF_G, and the third color filter CF_B overlap may be formed.

The optical layer LRL may have a refractive index greater than those of layers forming the color filters CF. The optical layer LRL may have a refractive index smaller than that of the color conversion layer CCL, and may form an optical recycling structure.

The optical layer LRL may include various suitable materials to have one refractive index. For example, the optical layer LRL may include various suitable resins and hollow silica. In some examples, the optical layer LRL may include a zirconium oxide (ZrOx). However, the present disclosure is not limited thereto. The optical layer LRL may have a refractive index lower than that of the color conversion layer CCL, and may form an optical recycling structure. In some embodiments, the optical layer LRL may be referred to as a low refractive index layer.

The upper layer UL may be disposed on the color filter layer CFL. The upper layer UL may be a substrate on which the color filter layer CFL is disposed. In some examples, the upper layer UL may include a functional film layer (e.g., an anti-reflection film, a polarizing film layer, or the like).

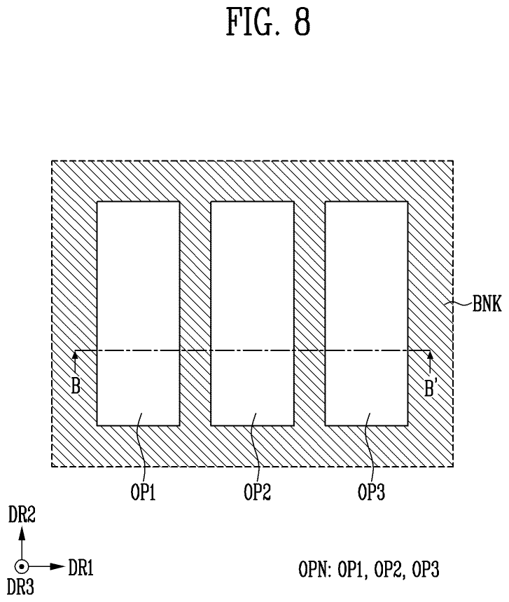

The display device DD according to some other embodiments will be described with reference to FIG. 8 to FIG. 11. Descriptions that may be redundant to those provided above are either simplified or are not repeated.

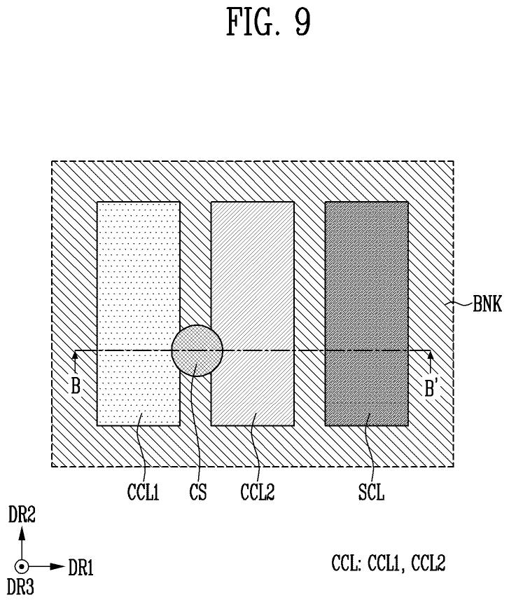

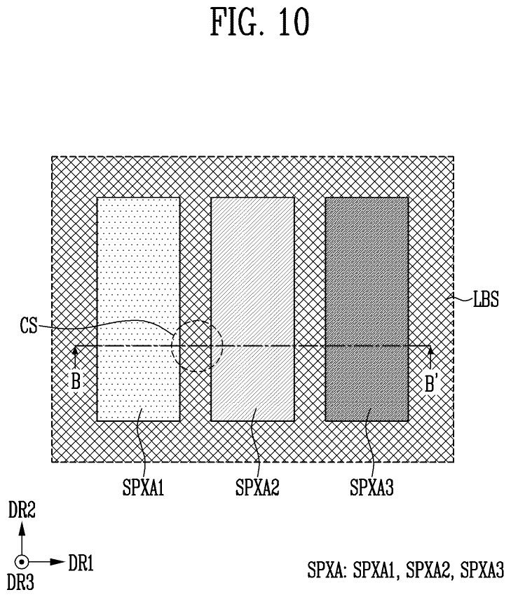

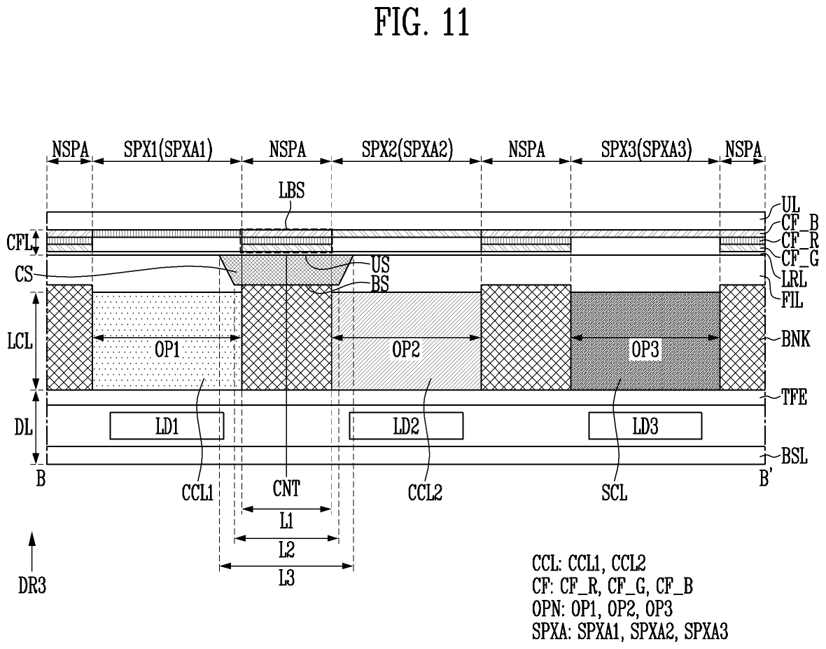

FIG. 8 to FIG. 10 illustrate schematic top plan views of a display device according to some other embodiments of the present disclosure. FIG. 11 illustrates a schematic cross-sectional view taken along the line B-B′ of FIG. 8 to FIG. 10, according to some other embodiments of the present disclosure. FIG. 8 to FIG. 10 illustrate first to third sub-pixels SPX1 to SPX3 of the same area. FIG. 8 schematically illustrates a bank BNK. FIG. 9 schematically illustrates a bank BNK, a color conversion layer CCL, and a scattering layer SCL. FIG. 10 schematically illustrates a light blocking structure LBS. Based on FIG. 11, a disposition relationship of the components may be more clearly understood.

Referring to FIG. 8 to FIG. 11, the display device DD according to some other embodiments is different from the display device DD according to embodiments described above in that the opening OPN does not overlap the light blocking structure LBS.

In some embodiments, when viewed in a plan view, the opening OPN may not overlap the light blocking structure LBS. When viewed in a plan view, the light blocking structure LBS may not overlap the sub-pixel area SPXA and may be disposed within the non-sub-pixel area NSPA.

In some embodiments, the first to third sub-pixel areas SPXA1 to SPXA3 may be spaced apart from each other in the first direction DR1. The first sub-pixel area SPXA1 may be disposed between the second sub-pixel area SPXA2 and the third sub-pixel area SPXA3.

In some embodiments, when viewed in a plan view, the spacer CS may overlap the first opening OP1, the second opening OP2, and the bank BNK.

In addition, referring to FIG. 11, in a cross-sectional view, the spacer CS may be disposed between the bank BNK and the color filter layer CFL. A portion of the upper surface US of the spacer CS may overlap the light blocking structure LBS, and the remaining portion thereof may overlap the sub-pixel area SPXA. A portion of the lower surface BS of the spacer CS may overlap the bank BNK, and the remaining portion thereof may overlap the opening OPN.

In some embodiments, the length L1 of the bank BNK overlapping the spacer CS may be shorter than the length L2 of the lower surface BS of the spacer CS. In a cross-sectional view, the length L1 of the bank BNK may be shorter than the length L3 of the upper surface US of the spacer CS. That is, the diameter of the spacer CS may be greater than the width of the bank BNK overlapping the spacer CS.

In some embodiments, the length L3 of the upper surface US of the spacer CS may be longer than the length L2 of the lower surface BS of the spacer CS. Accordingly, the spacer CS may have a cross-section of an inverted trapezoidal shape.

In addition, in a cross-sectional view, the center of the spacer CS and the center of the bank BNK may coincide (e.g., align). For example, the center of the spacer CS and the center of the bank BNK may coincide (e.g., align) at the center point CNT.

As a portion of the upper surface US of the spacer CS overlaps the sub-pixel area SPXA, the spacer CS may be made of a material having the same refractive index as the filling layer FIL to prevent or substantially reduce light loss.

The light emitting element LD formed in the display layer DL may be disposed in each of the sub-pixel areas SPXA. For example, the light emitting element LD may include the first light emitting element LD1 included in the first sub-pixel SPX1 and disposed within the first sub-pixel area SPXA1, the second light emitting element LD2 included in the second sub-pixel SPX2 and disposed within the second sub-pixel area SPXA2, and the third light emitting element LD3 included in the third sub-pixel SPX3 and disposed within the third sub-pixel area SPXA3.

In some embodiments, the first to third light emitting elements LD1 to LD3 may be configured to emit light including a light component of the third color. For example, the first to third light emitting elements LD1 to LD3 may emit light of the third color in the same manner. In some examples, in some embodiments, the first to third light emitting elements LD1 to LD3 may be configured to emit light including a light component of the second color and a light component of the third color. For example, the first to third light emitting elements LD1 to LD3 may emit light of a color that is a mixture of a light component of the second color and a light component of the third color.

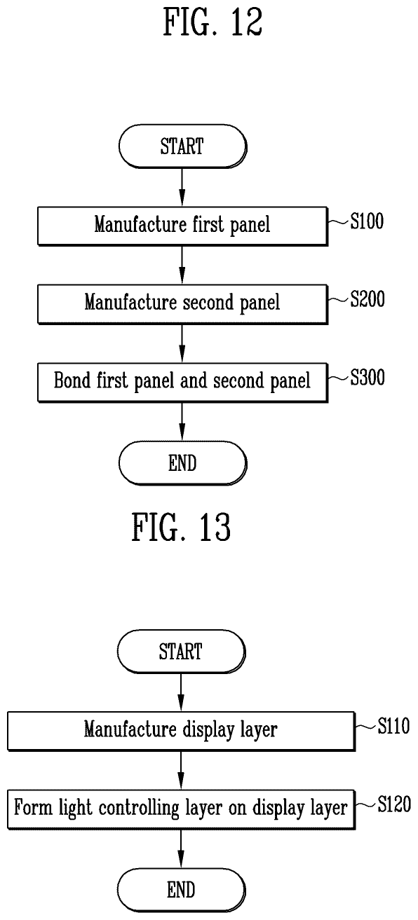

FIG. 12 illustrates a flowchart of a manufacturing method of a display device according to some embodiments. Referring to FIG. 2 and FIG. 12, a manufacturing method of the display device DD according to some embodiments may include manufacturing the first panel (S100), manufacturing the second panel (S200), and bonding the first panel and the second panel (S300).

In act S100, the first panel in which the light controlling layer LCL is disposed on the display layer DL including the base layer BSL may be manufactured.

In act S200, the second panel in which the color filter layer CFL is disposed on the upper layer UL may be manufactured.

In act S300, the filling layer FIL may be interposed between the first panel and the second panel, so that the first panel and the second panel may be bonded to manufacture the display device DD.

Referring to FIG. 12, it is shown that the second panel is manufactured after the first panel is manufactured, but the present disclosure is not limited thereto. For example, the first panel may be manufactured after the second panel is manufactured. In addition, the manufacturing of the first panel and the second panel may be concurrently (e.g., simultaneously performed).

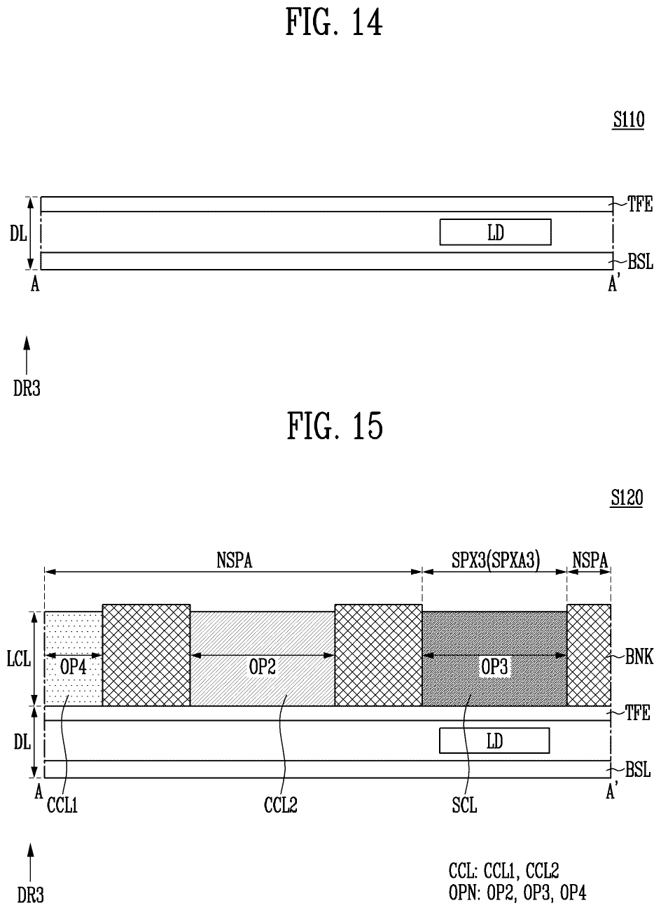

FIG. 13 illustrates a flowchart of the manufacturing of the first panel of FIG. 12. FIG. 14 and FIG. 15 illustrate schematic views of the process of the manufacturing method of the display device of FIG. 13.

Referring to FIG. 14, in act S100 of manufacturing the first panel, act S110 of manufacturing the display layer may be performed.

In act S110 of manufacturing the display layer DL, the layers forming the display layer DL may be disposed on the base layer BSL.

In some embodiments, the conductive layer or the insulating layer on the base layer BSL may be formed based on a typical process for manufacturing a semiconductor device. For example, the conductive layer or the insulating layer on the base layer BSL may be formed by a photolithography process, etched by various suitable methods (wet etching, dry etching, and the like), and deposited by various suitable methods (sputtering, chemical vapor deposition, and the like). However, the present disclosure is not necessarily limited to these particular examples.

In act S110, referring to FIG. 3 together, the pixel circuit PXC may be patterned on the base layer BSL to form the pixel circuit layer PCL, and the light emitting element LD may be disposed on the pixel circuit layer PCL.

In some embodiments, in act S110, the light emitting element LD may be disposed on the base layer BSL (e.g., the pixel circuit layer PCL) by various suitable methods. In some embodiments, the encapsulation layer TFE may be formed on a substantially uppermost portion of the display layer DL.

In act S110, referring to FIG. 3 together, the light emitting element LD may include an organic light emitting diode, and the light emitting element LD may be manufactured on the base layer BSL by a deposition process.

Referring to FIG. 12, FIG. 13, and FIG. 15, in act S100 of manufacturing the first panel, act S120 of forming the light controlling layer on the display layer may be performed.

In act S120 of forming the light controlling layer LCL on the display layer DL, the bank BNK, the color conversion layer CCL, and the scattering layer SCL may be formed.

In act S120, the bank BNK may be disposed on the display layer DL (e.g., the encapsulation film TFE). The bank BNK may be disposed in a partial area on the pixel circuit layer PCL, and areas for forming the sub-pixel areas SPXA may be substantially defined as subsequent processes are performed.

For example, referring to FIG. 4 together, in act S120, the first to fourth openings OP1 to OP4 surrounded by the bank BNK may be formed. The third opening OP3 may overlap the third sub-pixel area SPXA3 when viewed in a plan view.

In act S120, after the bank BNK is disposed, the first color conversion layer CCL1, the second color conversion layer CCL2, and the scattering layer SCL may be formed. For example, the first color conversion layer CCL1, the second color conversion layer CCL2, and the scattering layer SCL may be disposed within the openings OP respectively corresponding thereto. The first color conversion layer CCL1, the second color conversion layer CCL2, and the scattering layer SCL may be formed based on an inkjet process or a photolithography process. However, the present disclosure is not limited thereto.

In some embodiments, the first capping layer may be formed on the bank BNK, the color conversion layer CCL, and the scattering layer SCL. The first capping layer may cover other layers of the light controlling layer LCL. The first capping layer may passivate the bank BNK, the color conversion layer CCL, and the scattering layer SCL. The first capping layer may include an inorganic material.

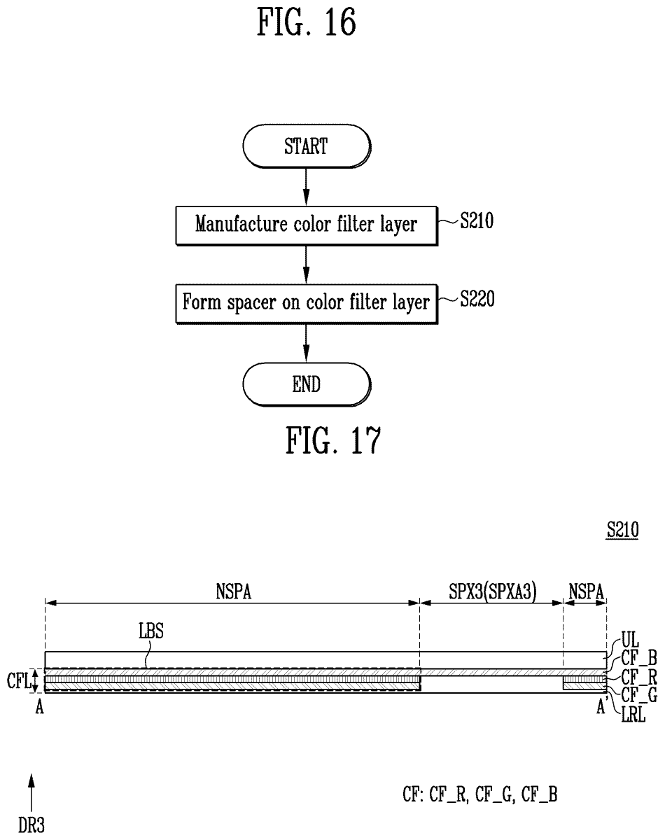

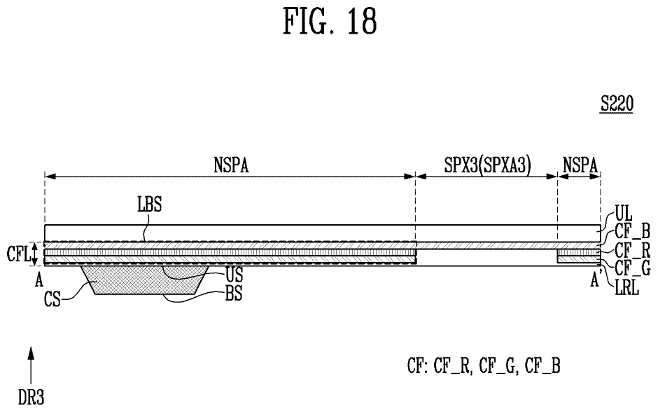

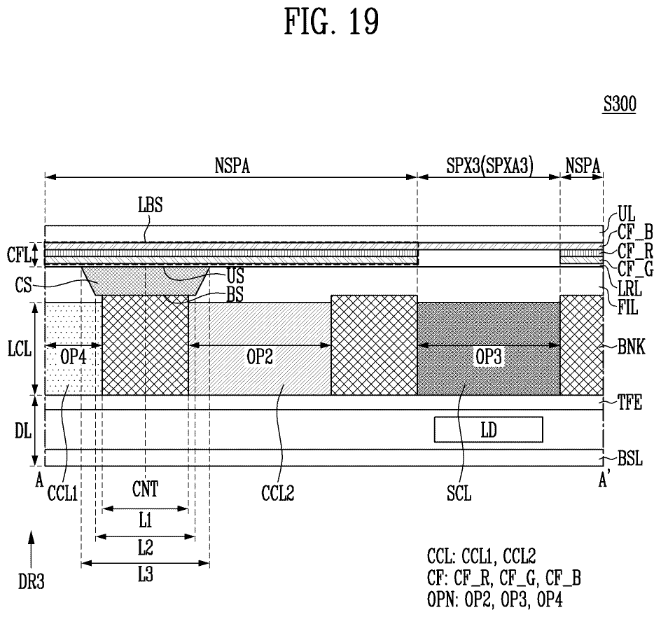

FIG. 16 illustrates a flowchart of the manufacturing of the second panel of FIG. 12, according to some embodiments of the present disclosure. FIG. 17 and FIG. 18 illustrate schematic views of the process of the manufacturing method of the display device of FIG. 16, according to some embodiments of the present disclosure.

Referring to FIG. 12 and FIG. 16 to FIG. 17, in act S200 of manufacturing the second panel, act S210 of manufacturing the color filter layer CFL may be performed.

In act S210, the layers forming the color filter layer CFL may be disposed on the upper layer UL. The color filters CF may be patterned on the upper layer UL based on a photolithography process, and accordingly, the first to third color filters CF_R, CF_G, and CF_B may be patterned to overlap the first to third sub-pixel areas SPXA1 to SPXA3, and the light blocking structure LBS may be formed in one area. The optical layer LRL may be formed on the color filters CF.

In some embodiments, the second capping layer may be formed on the optical layer LRL. The second capping layer may passivate other layers of the color filter layer CFL. The second capping layer may include an inorganic material.

Referring to FIG. 12, FIG. 16, and FIG. 18, in act S200 of manufacturing the second panel, act S220 of forming the spacer CS on the color filter layer CFL may be performed.

In act S220, the spacer CS may be patterned within an area overlapping the light blocking structure LBS. The length of the upper surface US of the spacer CS that is in contact with the color filter layer CFL may be longer than that of the lower surface BS of the spacer CS that is not in contact with the color filter layer CFL.

FIG. 19 illustrates a schematic view of the bonding of the first panel and the second panel of FIG. 12, according to some embodiments of the present disclosure.

Referring to FIG. 12 and FIG. 19, the first panel and the second panel may be bonded through the filling layer FIL.

In act S300, the first panel and the second panel may be bonded so that the center of the spacer CS coincides (e.g., aligns) with the center of one of the banks BNK. Referring to FIG. 19, the center of the spacer CS may coincide (e.g., align) with the center of the bank BNK disposed between the second opening OP2 and the fourth opening OP4.

In addition, the diameter of the spacer CS may be larger than the width of the bank BNK with which the spacer CS is in contact. For example, the width L1 of the bank BNK with which the spacer CS is in contact may be smaller than the length L2 of the lower surface BS of the spacer CS and the length L3 of the upper surface US thereof.

As the color conversion layer CCL, the first panel on which the scattering layer SCL are formed, and the second panel on which the spacer CS is formed are separately manufactured and then bonded, the color conversion layer CCL and the scattering layer SCL may be formed regardless of the process of the spacer CS. Accordingly, during the inkjet process of the color conversion layer CCL and the scattering layer SCL, an area in which the ink drop is provided may be secured, and process convenience may be improved.

Although the manufacturing method of some embodiments of FIG. 7 has been described with reference to FIG. 12 to FIG. 19, the present disclosure is not limited thereto, and some embodiments of FIG. 11 may be similarly manufactured.

However, in act S220, the spacer CS may be patterned to overlap the light blocking structure LBS and the sub-pixel area SPXA. For example, the upper surface of the spacer CS may overlap the first sub-pixel area SPXA1, the second sub-pixel area SPXA2, and the light blocking structure LBS.

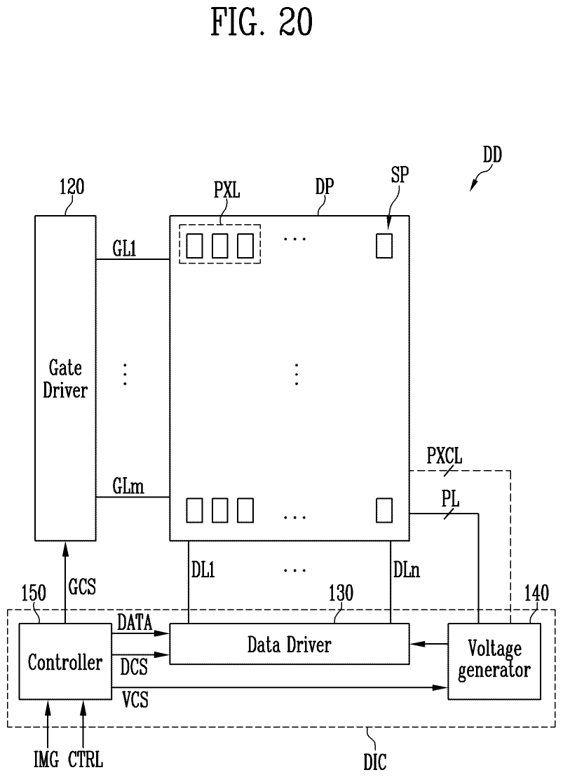

FIG. 20 illustrates a block diagram of a display device according to an embodiment.

Referring to FIG. 20, a display device DD may include a display panel DP, a gate driver 120, a data driver 130, a voltage generator 140, and a controller 150. The display device DD may be the display device DD of FIG. 1.

The display panel DP may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

The sub-pixels SP may generate light of two or more colors. For example, the sub-pixels SP may respectively generate light of a color, such as red, green, blue, cyan, magenta, yellow, or the like within the spirit and the scope of the disclosure.

Two or more of the sub-pixels SP may configure one pixel PXL. For example, the pixel PXL may include three sub-pixels as shown in FIG. 20. As such, the pixel PXL may emit light of various colors and various luminance depending on a combination of light emitted from the sub-pixels included therein.

The gate driver 120 is connected to the sub-pixels SP arranged (or disposed) in a row direction through the first to m-th gate lines GL1 to GLm. The gate driver 120 may output gate signals to the first to m-th gate lines GL1 to GLm in response to a gate control signal GCS. In embodiments, the gate control signal GCS may include a start signal indicating the start of each frame, a horizontal synchronization signal, and the like within the spirit and the scope of the disclosure.

The gate driver 120 may be disposed on one side or a side of the display panel DP. However, embodiments are not limited thereto. For example, the gate driver 120 may be divided into two or more physically and/or logically separated drivers, and the drivers may be disposed on one side or a side of the display panel DP and the other side of the display panel DP opposite to the one side or the side. As described above, the gate driver 120 may be disposed around the display panel DP in various forms according to the embodiments.

The data driver 130 is connected to the sub-pixels SP arranged in a column direction through the first to n-th data lines DL1 to DLn. The data driver 130 receives image data (DATA) and data control signal DCS from the controller 150. The data driver 130 operates in response to the data control signal DCS. In embodiments, the data control signal DCS may include a source start signal, a source shift clock, a source output enable signal, and the like within the spirit and the scope of the disclosure.

The data driver 130 may receive voltages from the voltage generator 140. The data driver 130 may use the received voltages to apply data signals having grayscale voltages corresponding to the image data (DATA) to the first to n-th data lines DL1 to DLn. In case that a gate signal is applied to each of the first to m-th gate lines GL1 to GLn, data signals corresponding to the image data DATA may be applied to the data lines DL1 to DLm. Accordingly, the sub-pixels SP may generate light corresponding to the data signals, and the display panel DP may display an image.

In an embodiment, the gate driver 120 and the data driver 130 may include complementary metal-oxide semiconductor (CMOS) circuit elements.

The voltage generator 140 may operate in response to a voltage control signal VCS from the controller 150. The voltage generator 140 is configured to generate voltages and provide the generated voltages to components of the display device DD, such as the gate driver 120, the data driver 130, and the controller 150. The voltage generator 140 may generate voltages by receiving an input voltage from the outside of the display device DD and regulating the received voltage.

The voltage generator 140 may generate a first power voltage and a second power voltage. The generated first and second power voltages may be provided to the sub-pixels SP through the power lines PL. In other embodiments, at least one of the first and second power voltages may be provided from the outside of the display device DD.

The voltage generator 140 may provide various voltages and/or signals. For example, the voltage generator 140 may provide one or more initialization voltages applied to the sub-pixels SP. For example, during a sensing operation to sense electrical characteristics of transistors and/or light emitting elements of the sub-pixels SP, a selectable reference voltage may be applied to the first to n-th data lines DL1 to DLn, and the voltage generator 140 may generate the reference voltage to transmit it to the data driver 130. For example, during a display operation for displaying an image on the display panel DP, common pixel control signals may be applied to the sub-pixels SP, and the voltage generator 140 may generate the pixel control signals. In embodiments, the voltage generator 140 may provide pixel control signals to the sub-pixels SP through a pixel control lines PXCL. FIG. 20 illustrates that the pixel control lines PXCL are connected between the voltage generator 140 and the display panel DP, but the embodiments are not limited thereto. For example, the pixel control lines PXCL may be connected between the gate driver 120 and the display panel DP. In this case, the pixel control signals may be transmitted from the voltage generator 140 to the pixel control lines PXCL through the gate driver 120.

The controller 150 controls various operations of the display device DD. The controller 150 receives input image data IMG and a control signal CTRL corresponding thereto, from the outside. The controller 150 may provide the gate control signal GCS, the data control signal DCS, and the voltage control signal VCS in response to the control signal CTRL.

The controller 150 may convert the input image data IMG to be suitable for the display device DD or the display panel DP to output the image data DATA. In embodiments, the controller 150 may output the image data DATA by aligning the input image data IMG to be suitable for the sub-pixels SP of a row unit.

Two or more components of the data driver 130, the voltage generator 140, and the controller 150 may be mounted on one integrated circuit. As shown in FIG. 20, the data driver 130, the voltage generator 140, and the controller 150 may be included in a driver integrated circuit DIC. In this case, the data driver 130, the voltage generator 140, and the controller 150 may be functionally separate components within or in one driver integrated circuit DIC. In other embodiments, at least one of the data driver 130, the voltage generator 140, and the controller 150 may be provided as a component separated from the driver integrated circuit DIC.

A display device according to an embodiment is applicable to various types of electronic devices. In an embodiment, an electronic device includes the above-described display device and may further include other modules or devices having additional functions in addition to the display device.

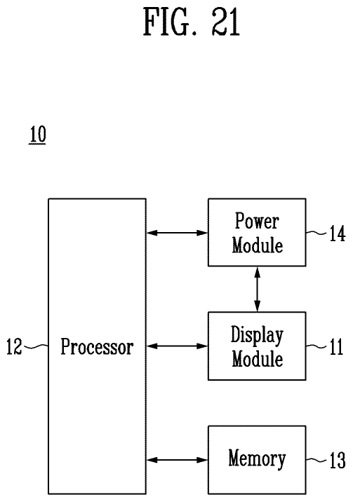

FIG. 21 is a block diagram of an electronic device according to an embodiment. Referring to FIG. 21, the electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device according to embodiments as described above. In addition, in terms of functionality, some of the individual modules included in one module may be included in the display device and others may be provided separately from the display device. For example, the display module 11 is included in the display device, whereas the processor 12, the memory 13, and the power module 14 are not included in the display device and are instead provided separately in the electronic device 10.

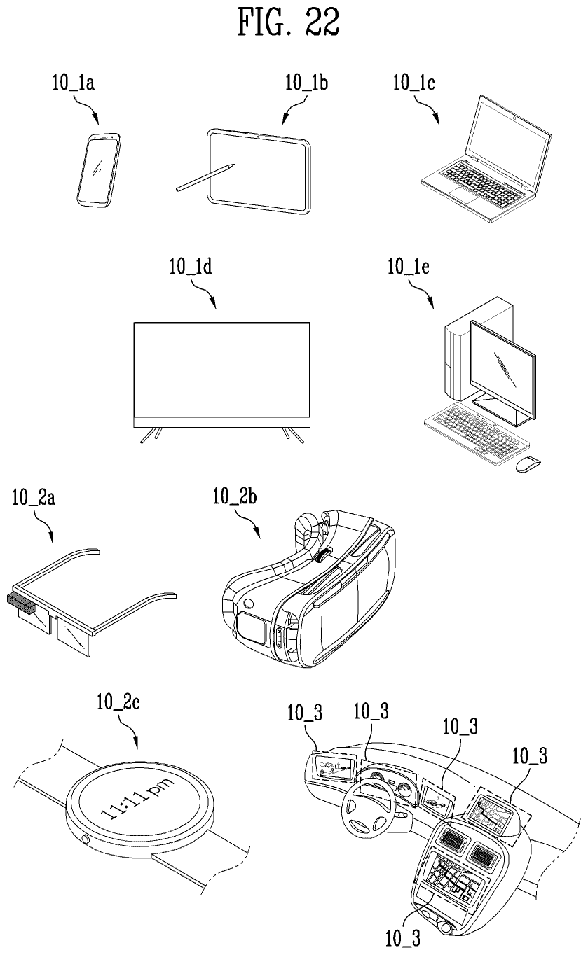

FIG. 22 shows schematic views of various embodiments of an electronic device.

Referring to FIG. 22, various types of electronic devices to which embodiments of a display device are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

The technical idea of the present disclosure has been specifically described according to the preferred embodiments, but it should be noted that the foregoing embodiments are provided only for illustration while not limiting the present disclosure. It will be understood by those skilled in the art that various suitable changes in form and details may be made therein without departing from the scope of the present disclosure, as defined by the following claims and their equivalents.

What is claimed is:

1. A display device comprising:
a display layer;
a light controlling layer on the display layer and comprising a bank and a color conversion layer; and
a color filter layer on the light controlling layer and comprising a color filter and a light blocking structure, the light controlling layer comprising:
an opening in which the bank is not positioned; and
a spacer between the bank and the light blocking structure and partially overlapping the opening.

2. The display device of claim 1, wherein a diameter of the spacer is larger than a width of the bank in which the spacer is positioned.

3. The display device of claim 2, wherein, in a cross-sectional view, a length of an upper surface of the spacer is longer than that of a lower surface of the spacer.

4. The display device of claim 3, wherein, in a cross-sectional view, the spacer has an inverted trapezoidal shape.

5. The display device of claim 3, wherein the upper surface of the spacer is adjacent to the color filter layer, and the lower surface of the spacer is adjacent to the bank.

6. The display device of claim 2, wherein, in a cross-sectional view, a center of the spacer coincides with a center of the bank in which the spacer is positioned.

7. The display device of claim 1, further comprising:
a sub-pixel area from which light of one color is emitted and a non-sub-pixel area outside the sub-pixel area,
wherein the sub-pixel area comprises a first sub-pixel area from which light of a first color is emitted, a second sub-pixel area from which light of a second color is emitted, and a third sub-pixel area from which light of a third color is emitted, and
wherein, when viewed in a plan view, the opening has a first opening overlapping the first sub-pixel area, a second opening overlapping the second sub-pixel area, and a third opening overlapping the third sub-pixel area.

8. The display device of claim 7, wherein a portion of the first opening, a portion of the second opening, and a portion of the third opening overlap the non-sub-pixel area.

9. A display device comprising:
a display layer;
a light controlling layer on the display layer and comprising a bank and a color conversion layer; and
a color filter layer on the light controlling layer and comprising a color filter and a light blocking structure, the light controlling layer comprising:
an opening in which the bank is not positioned; and
a spacer between the bank and the light blocking structure, a portion of an upper surface of the spacer overlapping the color filter, and a portion of a lower surface of the spacer overlapping the opening.

10. The display device of claim 9, wherein a diameter of the spacer is larger than a width of the bank in which the spacer is positioned.

11. The display device of claim 10, wherein, in a cross-sectional view, a length of the upper surface of the spacer is longer than that of the lower surface of the spacer.

12. The display device of claim 10, wherein the upper surface of the spacer is adjacent to the color filter layer, and the lower surface of the spacer is adjacent to the bank.

13. The display device of claim 10, wherein, in a cross-sectional view, a center of the spacer coincides with a center of the bank in which the spacer is positioned.

14. The display device of claim 9, wherein the display layer comprises a light emitting element that provides light to a light emitting area,
wherein the light emitting area overlaps the color filter and the color conversion layer when viewed in a plan view, and
wherein a portion of the spacer overlaps the light emitting area.

15. The display device of claim 9, wherein a filling layer is between the light controlling layer and the color filter layer, and
wherein the filling layer and the spacer have the same refractive index.

16. A manufacturing method of a display device, comprising:
manufacturing a first panel;
manufacturing a second panel; and
interposing a filling layer between the first panel and the second panel and bonding the first panel and the second panel,
wherein the manufacturing of the first panel comprises:
forming a color filter layer comprising a color filter and a light blocking portion on a first base layer; and
forming a spacer on the light blocking portion.

17. The manufacturing method of the display device of claim 16, wherein the manufacturing of the second panel comprises:
positioning a light emitting element layer comprising a light emitting element on a second base layer; and
positioning a color conversion layer comprising a bank protruding in a thickness direction of the second base layer and a color conversion unit within an area surrounded by the bank and comprising quantum dots.

18. The manufacturing method of the display device of claim 17, wherein the bonding of the first panel and the second panel comprises:
bonding the first panel and the second panel so that a center of the bank coincides with that of the spacer in a cross-sectional view.

19. The manufacturing method of the display device of claim 17, wherein a diameter of the spacer is larger than a width of the bank in which the spacer is positioned.

20. The manufacturing method of the display device of claim 17, wherein an upper surface of the spacer is adjacent to the first panel and a lower surface of the spacer is adjacent to the second panel, and
in a cross-sectional view, a length of the upper surface of the spacer is longer than that of the lower surface of the spacer.

21. An electronic device, comprising:
a processor to provide image data signals; and
a display device to display an image based on the image data signals;
the display device comprising:
a display layer;
a light controlling layer on the display layer and comprising a bank and a color conversion layer; and
a color filter layer on the light controlling layer and comprising a color filter and a light blocking structure, the light controlling layer comprising:
an opening in which the bank is not positioned; and
a spacer between the bank and the light blocking structure and partially overlapping the opening.

22. The electronic device of claim 21, wherein a diameter of the spacer is larger than a width of the bank in which the spacer is positioned.

23. The electronic device of claim 22, wherein, in a cross-sectional view, a length of an upper surface of the spacer is longer than that of a lower surface of the spacer.

24. The electronic device of claim 23, wherein, in a cross-sectional view, the spacer has an inverted trapezoidal shape.
